(19) United States
(12) Patent Application Publication
(10) Pub. No.: US 2020/0174063 A1
(43) Pub. Date: Jun. 4, 2020

(54) METHOD AND APPARATUS FOR TESTING SEMICONDUCTOR DEVICES WITH PREHEATING

(71) Applicant: SPIROX CORPORATION, Hsinchu City (TW)

(72) Inventors: TENG-CHUNG HUANG, HSINCHU CITY (TW); CHIH-CHIANG LEE, HSINCHU CITY (TW)

(21) Appl. No.: 16/661,325

(22) Filed: Oct. 23, 2019

Related U.S. Application Data
(60) Provisional application No. 62/774,941, filed on Dec. 4, 2018.

(51) Int. Cl. G01R 31/28; G01R 1/067; G01R 1/073

(52) U.S. Cl. CPC G01R 31/2863; G01R 1/07342; G01R 1/06722

(57) ABSTRACT

Embodiments of method and apparatus for testing a semiconductor device with a probe card having a first heater underneath prior to testing are provided herein, for heating the probe card to a first default temperature to keep the. A test carrier is heated to a second default temperature

### FIELD OF THE INVENTION

The present invention generally relates to method and apparatus for testing a device, in particular to method and apparatus for testing a semiconductor device, such as a wafer, with a preheating element.

### BACKGROUND OF THE INVENTION

In recent years, Integrated circuits (ICs) are manufactured and tested in a wafer before being diced from the wafer and mounted in packages, modules, or directly on a printed circuit board. Wafer level IC testing is a critical part of the IC manufacturing process that identifies the ICs to judge if the ICs function properly and provides feedback for improving product design and reducing manufacturing cost. Wafer level IC testing also prevents non-functioning ICs from going through the cost of packaging and in some applications can be used for stress testing or burn-in testing at high temperature to screen ICs to assure long-term reliability.

In the conventional wafer level IC testing, probe cards are used to provide an electrical path between a test device and the pads on integrated circuits in wafer form. The probe cards generally have electrical contact points (pogo pins) that match the size and density of the electrical pads on an IC and conductive patterns that provide an output of electrical signals from these high-density probes to the IC test device. The probe card is typically held in place above of the wafer, for moving the wafer into position to make an electrical connection between the IC pads and the probe tips of the probe card.

The semiconductor industry's growth has been driven by delivering smaller, more complex ICs, which requires the number of interconnect pads on each IC to increase while the size of each pad shrinks. Also, to reduce the cost of wafer testing IC manufacturers are testing a larger number of ICs at the same time. This higher parallelism improves the IC test device utilization and reduces the total wafer test time and thus reduces the overall cost of tests. The industry has introduced probe cards that can contact all of the ICs on a popular 300 mm wafer. These types of single touchdown memory probe cards may have up to 60,000 pins. These high pin count probe cards can require 2-5 grams of force for each probe to make contact during testing. This means that the probe card can exert a force of up to 300 Kg on the probe causing both the probe and the probe card to deflect and change the position of where the probes contact the IC pads. The traditional test devices for integrated circuit probe cards evolved from testing needle probe cards where there was a requirement to stop IC testing when yields dropped to analyze and adjust the needle's position and then go back to IC testing. The probe cards consist of an array of resilient conductors or wires terminating in an array of respective probe pins. The wires forming the array of probe points are mounted on a printed circuit board, and the probe points are positioned so that they are precisely aligned with the integrated circuit's bonding pads. A different probe card is generally used for each type of integrated circuit since the bonding pad patterns vary with each integrated circuit. During use, an integrated circuit is positioned below the probe array, with the probe pins aligned with respective bonding pads. The wafer and probe array are then brought together so that the probe pins slightly deflect as they make contact with their respective bonding pads. The electrical stimulus and the responses to the electrical stimulus are conducted through the probe card wired to suitable electronic testing devices. The probe card and the IC are then separated, and the probe pins are aligned with another IC on the wafer to repeat the test until all of the ICs on the wafer have been tested.

Refer to FIGS. 1A-E, they show a conventional semiconductor IC testing method and apparatus including an electronic test device, a probe card, and a test carrier. An electronic test device 10 usually placed on top of the probe card 20. The probe card 20 usually placed under the electronic test device 10 having two sides, one side having terminals matching with the electronic test device 10 and the other side having a plurality of pogo pins 22 matching the pattern of a device to be tested 32 on the test carrier 30. Referring to FIG. 1A shows the first step by placing the device to be tested 32 on the test carrier 30 and then moving the test carrier 30 to the bottom of the probe card 20. FIG. 1B shows a second step where the test carrier 30 is moved under the probe card 20 for heating the probe card 20 to deform. The heating process might take a long time approximately 6 to 10 minutes to complete. FIG. 1C shows a third step where the test carrier 30 is well heated and the probe card 20 is moved closer to the test carrier 30 for the plurality of pogo pins 22 to conductive the pattern of the device to be tested 32 to begin the test operation. FIG. 1D shows the fourth step after testing is completed, the test carrier 30 is moved away from the bottom of the probe card 20. FIG. 1E shows a fifth step wherein the device to be tested 32 has been completely tested and the test carrier 30 is been completely moved away from the bottom of the probe card 20 to remove the device already been tested and replace with a new device to be tested and repeat the entire steps in testing the new device to be tested.

The disadvantages of using the prior art's method is a time-consuming process, and after a device is tested completely, the test carrier has to move away to replace the device to be tested with a new device to test carrier. It will be led to that the probe card becomes cooler and needs to be heated to a working temperature again before new testing begins.

### SUMMARY OF THE INVENTION

An objective of the present invention is to provide method and apparatus for testing semiconductor devices with preheating, which heating a probe card and a plurality of pogo pins prior to installation for testing and heating the probe card to first default temperature, deforming the probe card and maintaining the temperature of the probe card during the testing process, for reducing the consumed time to heat the probe card again.

For above objective, the present invention discloses a method for testing a semiconductor device of the present invention comprising the steps of using a first heater to heat a probe card and a second heater to heat a device to be tested, and testing the device to be tested by electrically connecting a plurality of pogo pins of the probe card to the device to be tested; wherein the first heater and the second heater being at least a direct current heater or a hot air heater.

According to an embodiment of the present invention, wherein the first heater heats the probe card with half a temperature±10 DC of an actual temperature of the second heater.

According to an embodiment of the present invention, wherein the first heater and the second heater are direct current heater, hot air heater or combination thereof.

The present invention discloses a method for testing a semiconductor device comprising the steps of controlling a first heater to heat a probe card to a first default temperature and a second heater to heat an element to be tested to a second default temperature individually by a controller, testing the device to be tested by a plurality of pogo pins of the probe card electrically connecting to the device to be tested.

According to an embodiment of the present invention, wherein the first heater heats the probe card with half a temperature±10° C. of an actual temperature of the second heater.

According to an embodiment of the present invention, wherein the first heater and the second heater are direct current heater, hot air heater or combination thereof.

The present invention discloses a method for testing a semiconductor device comprising the steps of installing a first heater on a probe carrier placed underneath a probe card and heating the probe card to a first default temperature and stabilizing the deformation of the probe card during testing, wherein the probe card including a plurality of pogo pins. The method further including placing a device to be tested on a test carrier and heating the test carrier to a second default temperature and electrically connecting the plurality of pogo pins of the probe card to the test carrier for providing an electrical path between an electronic test device and the device to be tested to perform the testing, moving the test carrier away from a bottom of the probe card after completing the testing and replacing a new element to be tested while the first heater maintains the first default temperature.

According to an embodiment of the present invention, wherein the movement of said test carrier during the testing said probe card remains stable.

According to an embodiment of the present invention, wherein the first heater is a direct current heater or a hot air heater, and the test carrier further installed with a direct current heater or a hot air heater.

According to an embodiment of the present invention, after completely testing said first device to be tested, during the process of replacing said new element to be tested and beyond, the deformation of said probe card remains.

According to an embodiment of the present invention, wherein the first heater heats said probe card with half a temperature±10° C. of an actual temperature of a second heater disposed in the test carrier.

According to an embodiment of the present invention, wherein the first heater transfers heat to said probe card and the probe card transfer the heat to the plurality of pogo pins which eventually deformed said probe card.

The present invention discloses an apparatus for testing a semiconductor device of the present invention, comprising an electronic test device including a probe card having a plurality of pogo pins disposed under the electronic test device, and deposed a first heater underneath the probe card for heating the probe card to a first default temperature before testing and stabilizing the deformation of the probe card during testing; and a test carrier, carrying a device to be tested and being heated to a second default temperature.

According to an embodiment of the present invention, the apparatus for testing a semiconductor device of the present invention further comprising a controller device coupled to sense the temperatures of said probe card and said second test carrier and perform actions to regulate their temperatures at a default level.

According to an embodiment of the present invention, the apparatus for testing a semiconductor device of the present invention further comprising a second heater disposed in the test carrier to heat the test carrier to the second default temperature.

The present invention discloses an apparatus for testing a semiconductor device, comprising an electronic test device including a probe card having a plurality of pogo pins disposed under the electronic test device, and carrying a first heater underneath the probe card for heating the probe card to a first default temperature before testing and stabilizing the deformation of the probe card during testing; and a test carrier, carrying a device to be tested and being heated to a second default temperature.

According to an embodiment of the present invention, the apparatus further comprising a controller device coupled to sense the temperatures of the probe card and the test carrier and perform actions to regulate their temperatures at a default level.

According to an embodiment of the present invention, the apparatus further comprising a second heater disposed in the test carrier to heat the test carrier to the second default temperature.

According to an embodiment of the present invention, wherein the probe card is deformed due to a high-temperature state of the first heater and the test carrier.

### BRIEF DESCRIPTION OF THE DRAWINGS

FIGS. 1A-E show the steps of the conventional method of testing a semiconductor device according to the prior art.

FIGS. 2A-E show the steps of the method for testing a semiconductor device according to one embodiment of the present disclosure.

FIGS. 3A-C show a perspective view of how the first heater is attached to the probe card 20 in accordance with another embodiment of the present invention.

FIGS. 4A-C show a perspective view of how the first heater is attached to the probe card in accordance with another embodiment of the present invention.

FIGS. 5A-B show a perspective view of how the first heater is placed inside a probe card in accordance with another embodiment of the present invention.

FIGS. 6A-B show a perspective view of an apparatus for testing a semiconductor device with a hot-air heating device coupled to the probe card for heating the heating element for testing a semiconductor device according to another embodiment of the present disclosure.

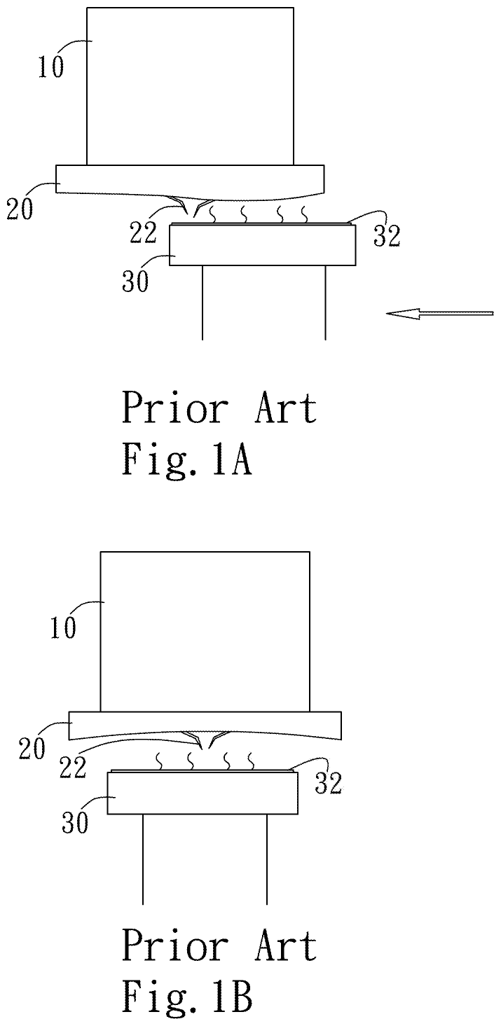

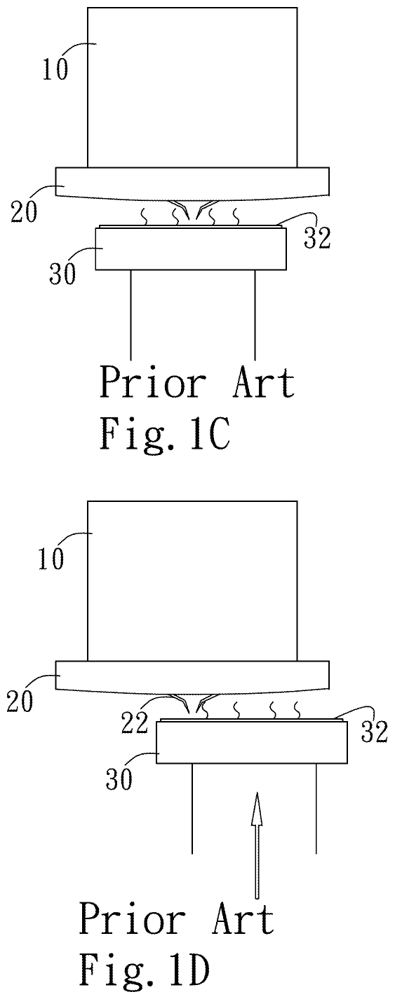

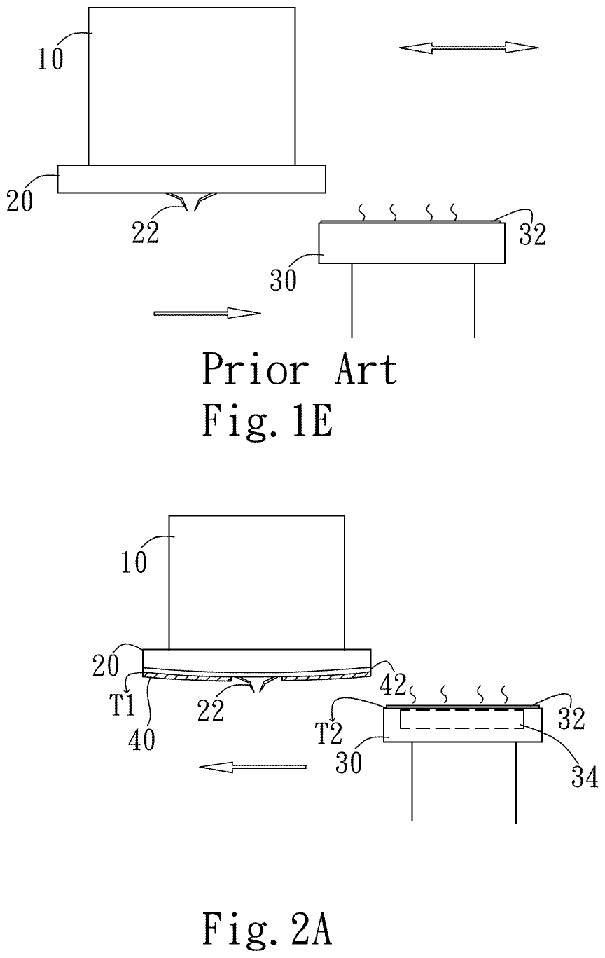

### DETAILED DESCRIPTION OF PREFERRED EMBODIMENT

This specification describes exemplary embodiments and applications of the invention. The invention, however, is not limited to these exemplary embodiments and applications or to the manner in which the exemplary embodiments and applications operate or are described herein. In addition, as the terms “on” and “attached to are used herein, one object (e.g., a material, a layer, a Substrate, etc.) can be “on” or “attached to another object regardless of whether the one object is directly on or attached to the other object or there are one or more intervening objects between the one object and the other object. Also, directions (e.g., above, below, top, bottom, side, up, down, “X.” “Y.” “Z. etc.), if provided, are relative and provided solely by way of example and for ease of illustration and discussion and not by way of limitation. In addition, where reference is made to a list of elements (e.g., elements A, B, C). Such reference is intended to include any one or more of the listed elements by itself or in any combination.

The conventional test process is directed to an test carrier stage and determined that it is easier to properly position a wafer on the test carrier, together with the desired theta orientation of the wafer with respect to the test carrier, when the carrier stage is extended at least partially outside of the chamber. Unfortunately, in the event that the test carrier is heated or cooled, such as to 300 degrees Celsius or cooled significantly below ambient temperature, placing an ambient temperature wafer on the carrier tends to result in damage to the devices on the wafer or otherwise results in fracturing the wafer itself. In either case, the wafer is susceptible to becoming damaged. In some cases, the user could manually hold the wafer on a wafer holder in the vicinity of the test carrier until the wafer is sufficiently heated, but this is difficult at best, for the user to accomplish. Further, it is difficult to achieve similar such temperatures using a wafer holder because of the insulating effect of the wafer holder and the distance of the wafer from the surface of the test carrier. Also, the user has a tendency to accidentally touch the surface of the carrier with his hand, thus resulting in painful burning or freezing of his hand. In addition, even with a test carrier at ambient temperature the wafer is typically placed on the upper surface of the carrier using a motion that is at an acute angle to the upper surface of the carrier, and accordingly, the wafer tends to slide across the carrier surface thus coming to rest at a non-desirable location, if it remains on the chuck at all. The probe card must be designed to compensate for any mechanical movement due to heating of the wafer from the power generated by integrated circuits or by the prober performing high-temperature testing as a reliability screen. The flexing or bending of the probe card under the force applied by the prober during testing must be limited, otherwise, the probe tips will not stay in electrical contact with the IC pads. The probe card must maintain low contact resistance, consistent probe force, and alignment during its operating life.

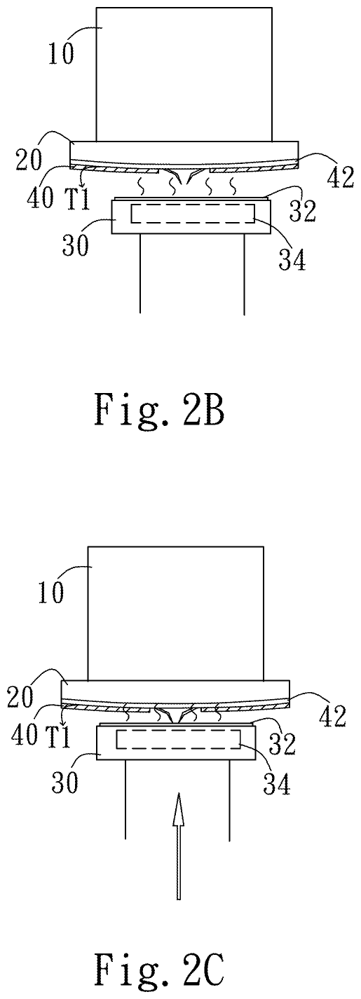

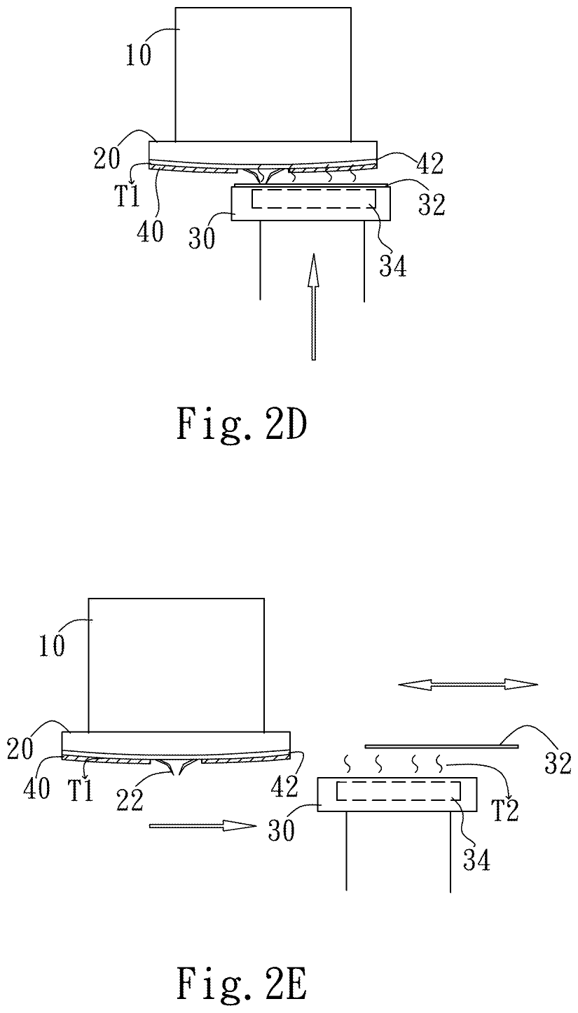

Refer to FIGS. 2A-E, they show the method and apparatus for testing a semiconductor device in accordance with one embodiment of the present disclosure, the testing apparatus includes an electronic test device 10, a probe card 20 placed underneath the electronic test device 10 and a test carrier 30 for carrying a device to be tested 32 (wafer). The probe card 20 is placed under the electronic test device 10 has two having two sides, one side having terminals matching with the electronic test device 10 and the other side having a plurality of pogo pins 22 matching the pattern of a device to be tested 32 mounted on the test carrier 30. The probe card 20 of the present invention compared to prior arts is including a first heater 40 disposed underneath the probe card 20 for heating the probe card 20 to a first default temperature T1 before testing and stabilizing the deformation of the probe card during testing. The second carries 30, sometimes refers to as a wafer carrier or wafer chunk including a second heater 34 for heating the test carrier 30 to a second default temperature T2 before testing. The test carrier 30 is responsible for loading, carrying and unloading the device to be tested 32 during testing. The test carrier 30 is always heated by the second heater 34 to the second default temperature T2 before beginning the testing process.

As shown in FIG. 2A, the first step of the testing method of the present invention by using the first heater 40 to heat the probe card 20 and the second heater 34 to heat a device to be tested 32, wherein the device to be tested 32 is already loaded on the test carrier 30 and heated to the second default temperature and then moving the test carrier 30 to the bottom of the probe card 20. The probe card 20 already installed under the electronic terser 10 and preheated by the first heater 40. As shown in FIG. 2B, the second step of the testing method of the present invention, wherein test carrier 30 is completely moved under the probe card 20 to conduct the testing. According to the prior arts, when the test carrier 30 is moved under the probe card 20, it requires a longer time (such as 6 to 10 minutes) to heat the probe card 20 by the second heater 34 to the first default temperature T1. However, the present invention might take a lesser time (such as 2 to 3 minutes) to completely heat the probe card 20 because of the installment of the first heater 40 to preheat the probe card 20 and deformed the probe card 20 before beginning the testing.

Continuously, As shown in FIG. 2C, the third step of the testing method of the present invention, wherein heating both the probe card 20 and test carrier 30 is completed and the probe card 20 is moved closer to the test carrier 30 for the plurality of pogo pins to match the pattern of the device to be tested 32 to begin testing. As shown in FIG. 2D, the fourth step of the testing method of the present invention wherein when testing is completed, the test carrier 30 is moved away from the bottom of the probe card 20. As shown in FIG. 2E, the fifth step of the testing method of the present invention wherein the device to be tested 32 is completely tested and the test carrier 30 is also completely moved away from the bottom of the probe card 20 to unload the device already tested and reload a new device to be tested and repeat the steps for testing the new device to be tested. In comparison to the prior art, the present invention is less time consuming and more reliable because of the first heater 40 attached to the probe card 20 for heating the probe card to a first default temperature T1 and stabilizing the deformation of the probe card 20 during entire testing. In accordance with the present invention, the first heater 40 and the second heater 34 are the direct current heater or the hot air heater or combination thereof.

### Example 1

TABLE 1

| | The temperature of | The temperature of |
|---|---|---|
| | the test carrier | the first heater |
| 1 | 85° C. | 32.5° C.~52.5° C. |
| 2 | 100° C. | 40° C.~60° C. |
| 3 | 125° C. | 52.5° C.~72.5° C. |

As shown in Table 1, when the actual temperature of the test carrier is 85° C., the actual temperature set on the first heater 40 to heat the probe card 20 would be balanced to only about 32.5° C.˜52.5° C., when the actual temperature of the test carrier 30 is 100° C., the actual temperature set on the first heater 40 to heat the probe card 20 would be higher to only about 40° C.˜60° C., and so and so forth. Thus, the first heater heats the probe card with half a temperature±10° C. of an actual temperature of the second heater 34. As a result of the movement of the test carrier 30 during the testing, the probe card 20 of the present invention will remain stable.

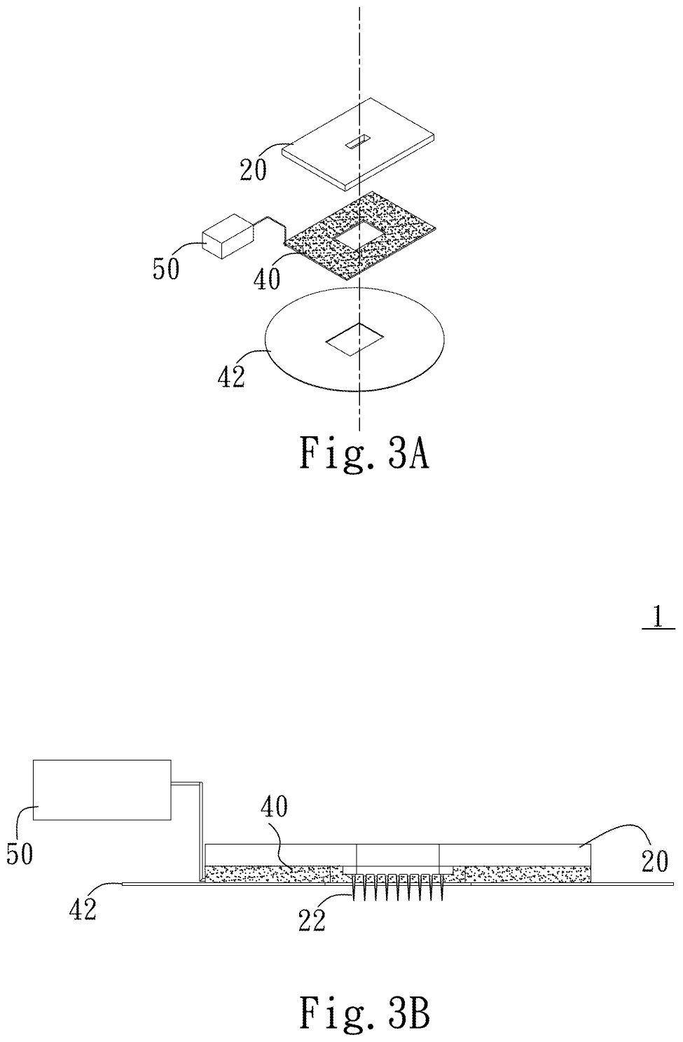

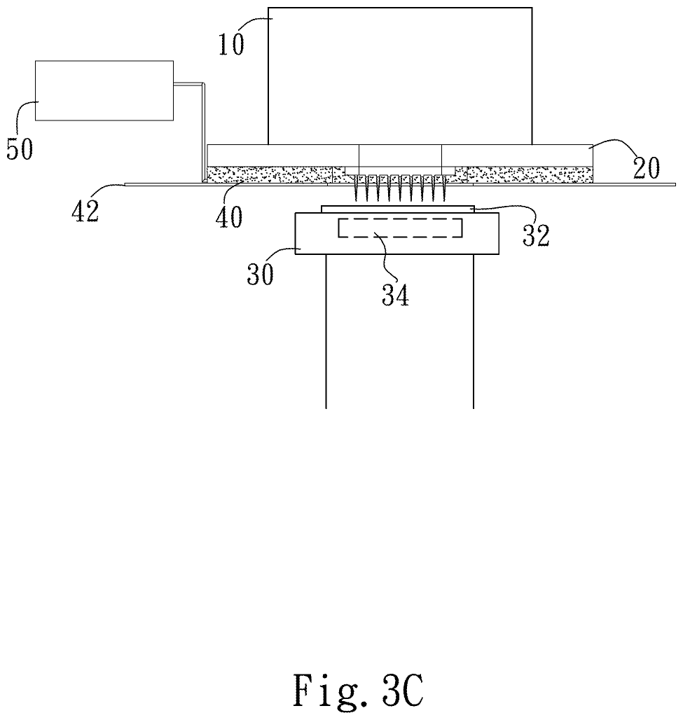

Referring to FIGS. 3A-C, they show a perspective view of how the first heater 40 is attached to the probe card 20 in accordance with another embodiment of the present invention. The structure of the attachment includes a probe card 20 having a plurality of pogo pins 22, a first heater 40, a probe carrier 42 and a controller device 50. The probe carrier 42 is placed underneath the first heater 40 for carrying the heating element 40. The first heater 40 might be disposed on the probe carrier 42 and then attached under the probe card 20 for heating the probe card. the controller device 50 is coupled to the first heater 40 for sensing the temperature of the probe card 20 through the first heater 40. The controller device 50 also performs actions to regulate the temperature of the probe card 20 to a first default level.

During the testing process, the probe card 20 having the plurality of pogo pins 22 attached underneath the electronic test device 10 and the test carrier 30 carrying the device to be tested 32. After the first heater 40 heats the probe card 20 and the second heater 34 heats the device to be tested 32. The test carrier 30 is moved to the bottom of the probe card 20, then the electronic test device 10 with the probe card 20 moves down allowing the plurality of pogo pins 22 contacting with the device to be tested 32 on top of the test carrier 30 to conduct the testing.

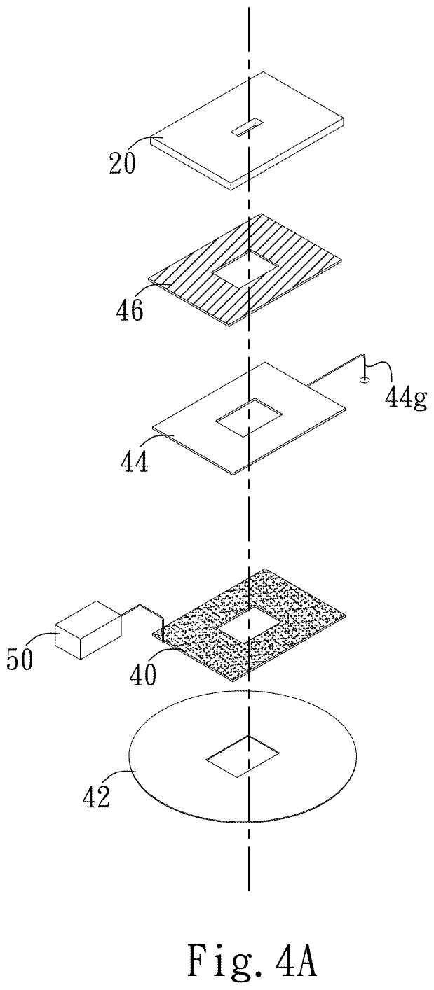

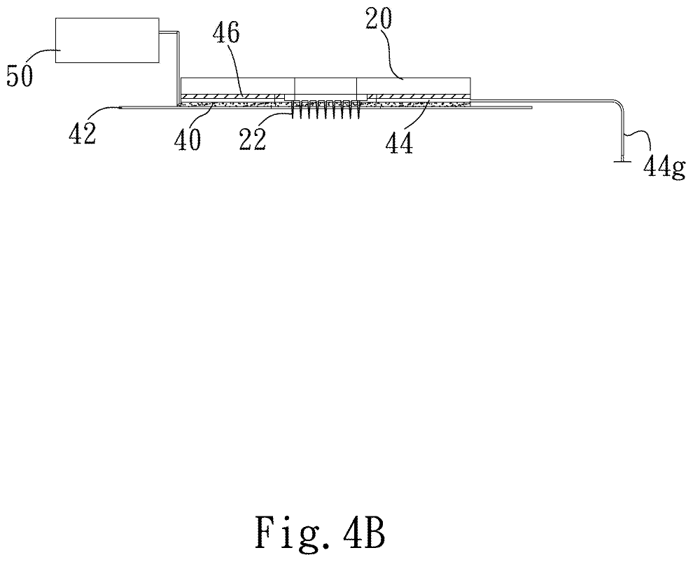

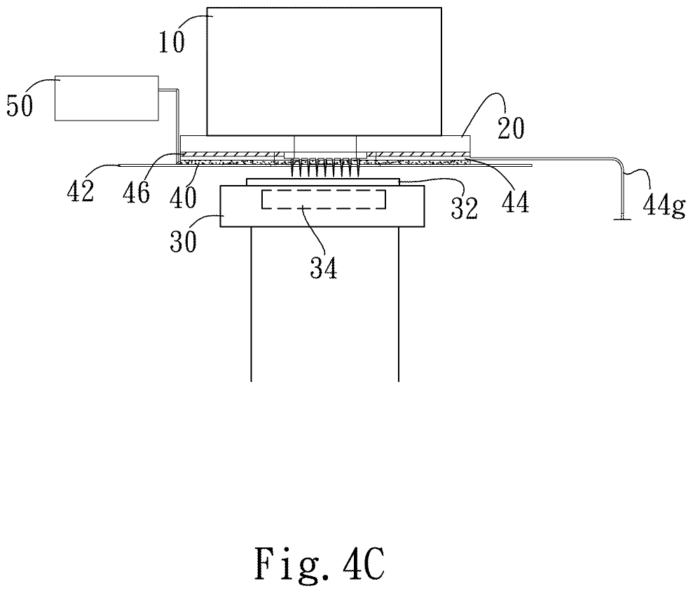

FIGS. 4A-C show a perspective view of how the first heater 40 is attached to the probe card 20 in accordance with another embodiment of the present invention. The apparatus of the present invention includes a probe carrier 42, first heater 40, a controller device 50, an electromagnetic isolation layer 44, a thermal adhesive layer 46 and a probe card 20. The probe carrier 42 is placed underneath the first heater 40 for carrying the heating element 40. The first heater 40 might be disposed on the probe carrier 42 and then attached under the probe card 20 for heating the probe card 20. The electromagnetic isolation layer 44 having a ground line 44g might be disposed on the first heater 40 to enclosures and isolate magnetic fields surroundings the first heater 40. The thermal adhesive layer 46 might be disposed between the electromagnetic layer 44 and the probe card 20 to distribute the temperature equally around the probe card 20 and the controller device 50 is coupled to the first heater 40 for sensing the temperature of the probe card 20 through the first heater 40. The controller device 50 also performs actions to regulate the temperature of the probe card 20 to a first default temperature level during testing.

During the testing process, the probe card 20 having the plurality of pogo pins 22 attached underneath the electronic test device 10 and the test carrier 30 carrying the device to be tested 32. After the first heater 40 heats the probe card 20 and the second heater 34 heats the device to be tested 32. The test carrier 30 is moved to the bottom of the probe card 20, then the electronic test device 10 with the probe card 20 moves down allowing the plurality of pogo pins 22 contacting with the device to be tested 32 on top of the test carrier 30 to conduct the testing.

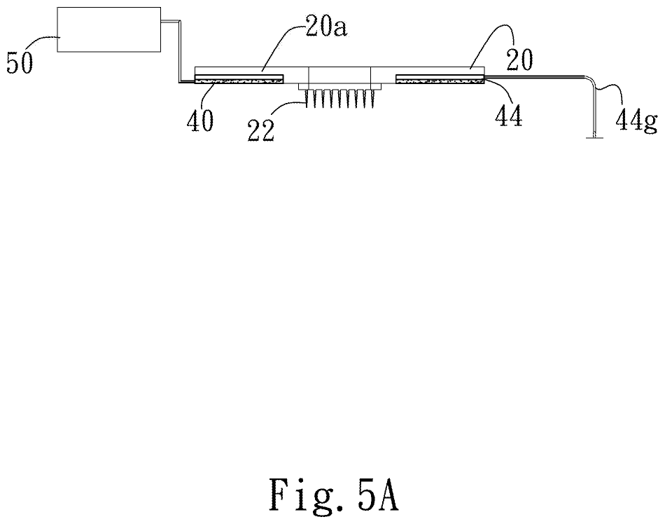

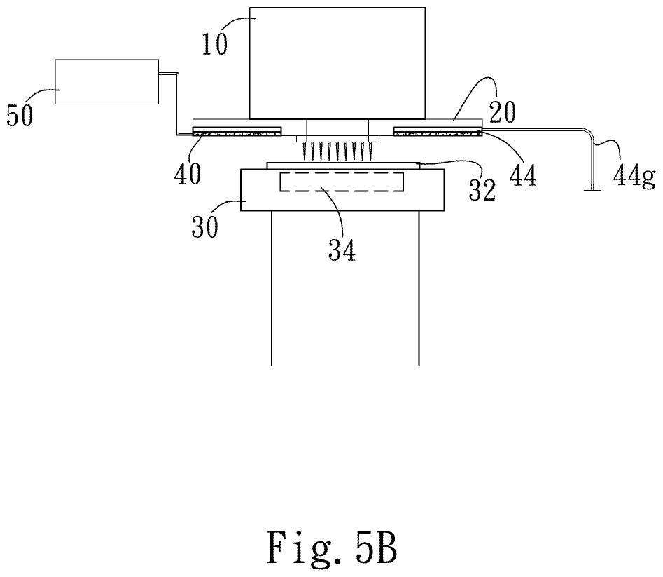

Refer to FIGS. 5A-B, they show a perspective view of how the first heater 40 is placed inside the probe card 20 in accordance with another embodiment of the present invention. The apparatus of the present invention including a probe card 20 wherein the first heater 40 may be placed inside the probe card 20. The structure including a probe card 20 having a plurality of pogo pins 22 also including a space 20a to contain the first heater 40 and the electromagnetic isolation layer 44. The first heater 40 heats and maintain the deformation of the probe card during the testing process and the electromagnetic isolation layer 44 having a ground line 44g is disposed on the first heater 40 to enclosure and isolate magnetic fields surroundings the first heater 40. The structure also includes a controller device 50 coupled to the probe card 20 for sensing and regulating the temperature of the probe card 20 during the testing process.

During the testing process, the probe card 20 having the plurality of pogo pins 22 attached underneath the electronic test device 10 and the test carrier 30 carrying the device to be tested 32. After the first heater 40 heats the probe card 20 and the second heater 34 heats the device to be tested 32. The test carrier 30 is moved to the bottom of the probe card 20, then the electronic test device 10 with the probe card 20 moves down allowing the plurality of pogo pins 22 contacting with the device to be tested 32 on top of the test carrier 30 to conduct the testing.

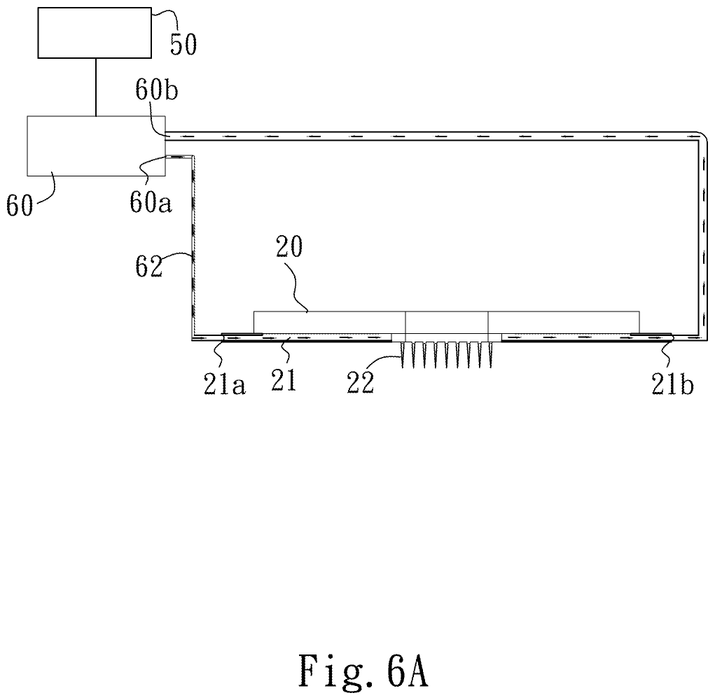

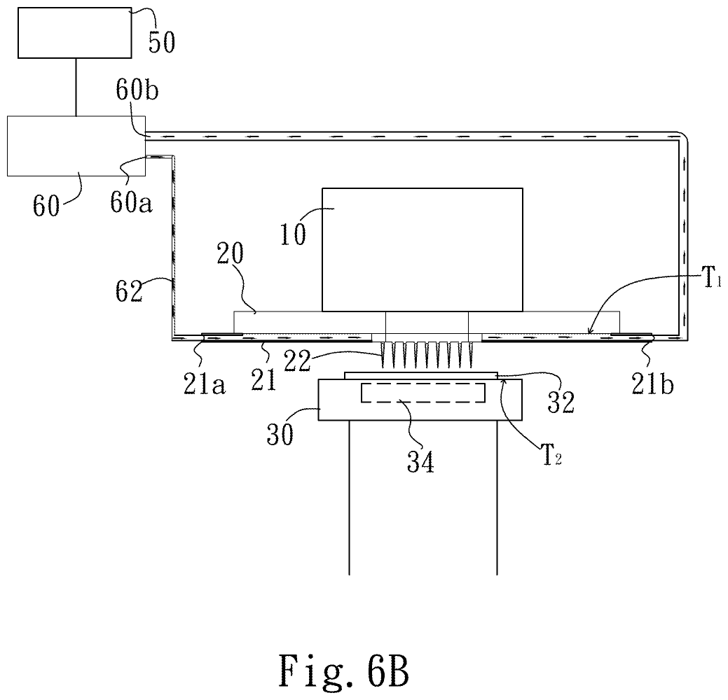

Refer to FIGS. 6A-B, they show a hot air machine may be provided to facilitate circulating hot air within the probe card 20 in accordance with another embodiment of the present invention. As shown in FIGS. 6A-B, this embodiment including a probe card 20 having a plurality of pogo pins 22 and a vacuum 21, while the vacuum 21 having an inlet 21a and an outlet 21b. A controller device 50 is coupled to the hot air machine 60 to control the hot air machine 60 and regulates the temperature of the probe card 20 to the first default temperature level. The hot air machine 60 generating a hot air 62, and having a first opening 60a and a second opening 60b. The first opening may be coupled to the inlet 21a of the vacuum 21 of the probe card 20 for allowing the hot air to pass through the vacuum 21 of the probe card 20, and the second opening 60b of the hot air machine 60 may be coupled to the outlet 21b of the vacuum 21 of the probe card 20 for allowing the hot air to come out and go back to the hot air machine 60. The circulation of the hot air 62 within the vacuum 21 may facilitate heating the probe card 20, the plurality of pogo pins 22 and maintaining the deformation the probe card 20 before and during testing.

During the testing process, the probe card 20 having the plurality of pogo pins 22 attached underneath the electronic test device 10 and the test carrier 30 carrying the device to be tested 32. After the first heater 40 heats the probe card 20 and the second heater 34 heats the device to be tested 32. The test carrier 30 is moved to the bottom of the probe card 20, then the electronic test device 10 with the probe card 20 moves down allowing the plurality of pogo pins 22 contacting with the device to be tested 32 on top of the test carrier 30 to conduct the testing.

What is claimed is:

1. A method for testing a semiconductor device, comprising steps of:
using a first heater to heat a probe card and a second heater to heat a device to be tested; and
testing said device to be tested by electrically connecting a plurality of pogo pins of said probe card to said device to be tested.

2. The method of claim 1, wherein said first heater heats said probe card with half a temperature±10° C. of an actual temperature of said second heater.

3. The method of claim 1, wherein said first heater and said second heater are direct current heater, hot air heater or combination thereof.

4. A method for testing a semiconductor device, comprising steps of:
controlling a first heater to heat a probe card to a first default temperature and a second heater to heat a device to be tested placed on top of a test carrier to a second default temperature individually by a controller device; and
testing a device to be tested by electrically connecting a plurality of pogo pins of said probe card to said device to be tested.

5. The method of claim 4, wherein said first heater heats said probe card with half a temperature±10° C. of an actual temperature of said second heater.

6. The method of claim 4, wherein said first heater and said second heater are direct current heater or hot air heater or combination thereof.

7. A method for testing a semiconductor device, comprising steps of:
installing a first heater on a probe carrier placed underneath a probe card and heating said probe card to a first default temperature and stabilizing the deformation of said probe card during testing, wherein said probe card including a plurality of pogo pins;
placing a device to be tested on a test carrier and heating said test carrier to a second default temperature;
electrically connecting said plurality of pogo pins of said probe card to said test carrier for providing an electrical path between an electronic test device and said device to be tested to perform said testing;
moving said test carrier away from a bottom of said probe card after completing the testing; and
replacing a new device to be tested while said first heater maintains said first default temperature.

8. The method of claim 7, wherein the movement of said test carrier during the testing said probe card remains stable.

9. The method of claim 7, wherein said first heater is a direct current heater or a hot air heater, and said test carrier further installed with a direct current heater or a hot air heater.

10. The method of claim 7, after completely testing said first device to be tested, during the process of replacing said new element to be tested and beyond, the deformation of said probe card remains.

11. The method of claim 7, wherein said first heater heats said probe card with half a temperature±10° C. of an actual temperature of a second heater disposed in the test carrier.

12. The method of claim 7, wherein said first heater transfers heat to said probe card and said probe card transfer the heat to said plurality of pogo pins which eventually deformed said probe card.

13. An apparatus for testing a semiconductor device, comprising:
an electronic test device;
a probe card, having a plurality of pogo pins disposed under said electronic test device, and deposed a first heater underneath aid probe card for heating said probe card to a first default temperature before testing and stabilizing the deformation of said probe card during testing; and
a test carrier, carrying a device to be tested and being heated to a second default temperature.

14. The apparatus of claim 13, further comprising a controller device coupled to sense the temperatures of said probe card and said test carrier and perform actions to regulate their temperatures at a default level.

15. The apparatus of claim 13, further comprising a second heater disposed in the test carrier to heat the test carrier to the second default temperature.

16. An apparatus for testing a semiconductor device, comprising:
an electronic test device, comprising:
a probe card having plurality of pogo pins disposed under said electronic test device, wherein a probe carrier, carrying a first heater is placed underneath said probe card for heating said probe card to a first default temperature and stabilizing the deformation of said probe card during testing; and
a test carrier, carrying a device to be tested and being heated to a second default temperature.

17. The apparatus of claim 16, further comprising a controller device coupled to said probe card for sensing a temperature of said probe card and perform actions to regulate said temperatures to a first default temperature level.

18. The apparatus of claim 16, further comprising a thermal adhesive layer glued under said probe card for distributing the temperature of said probe card equally around said probe card.

19. The apparatus of claim 16, wherein said probe card is deformed due to a high-temperature state of said first heater and said test carrier.

20. The apparatus of claim 16, further comprising a second heater disposed in the test carrier to heat the test carrier to the second default temperature.
